(19) United States
(12) Patent Application Publication
(10) Pub. No.: US 2026/0223359 A1
(43) Pub. Date: Jul. 30, 2026

(54) SEMICONDUCTOR DEVICE AND FORMATION METHOD THEREOF

(71) Applicant: Winbond Electronics Corp., Taichung City (TW)

(72) Inventors: Hao-Chuan CHANG, Taichung City (TW); Jiun-Sheng YANG, Taichung City (TW); Hung-Yu WEI, Taichung City (TW)

(21) Appl. No.: 19/442,240

(22) Filed: Jan. 7, 2026

(30) Foreign Application Priority Data
Jan. 24, 2025 (TW) 114103293

(51) Int. Cl. H10B 12/00

(52) U.S. Cl. CPC H10B 12/48; H10B 12/03

(57) ABSTRACT

A semiconductor device and a formation method thereof are provided. The semiconductor device includes a substrate, a contact pad, first and second conductive layers, a dielectric layer, a first contact, and an isolation element. The substrate includes a memory array area and a peripheral area. The contact pad is disposed on the substrate. The first conductive layer is disposed on the contact pad and in the memory array area. The dielectric layer is disposed on the first conductive layer and in the memory array area and the peripheral area. The second conductive layer is disposed on the dielectric layer and in the memory array area and the peripheral area. The first contact is disposed in the peripheral area and electrically connected to the contact pad in the peripheral area. The isolation element is disposed in the peripheral area and between the second conductive layer and the first contact.

### CROSS REFERENCE TO RELATED APPLICATIONS

This application claims priority of Taiwan patent application No. 114103293, filed on Jan. 24, 2025, the entirety of which is incorporated by reference herein.

### TECHNICAL FIELD

The present disclosure relates to a semiconductor device and a formation method thereof, and, in particular, it relates to a semiconductor device that includes an isolation element, and a formation method of the semiconductor device.

### BACKGROUND

As semiconductor devices continue to shrink, the size of memory continues to shrink to increase integration and improve performance. This continued miniaturization can lead to short circuits between components, which degrade the electrical performance of the memory.

### BRIEF SUMMARY

In some embodiments, a semiconductor device is provided. The semiconductor device includes a substrate, a contact pad, a first conductive layer, a dielectric layer, a second conductive layer, a first contact, and an isolation element. The substrate includes a memory array area and a peripheral area. The peripheral area is adjacent to the memory array area. The contact pad is disposed on the substrate. The first conductive layer is disposed on the contact pad and in the memory array area. The dielectric layer is disposed on the first conductive layer and in the memory array area and the peripheral area. The second conductive layer is disposed on the dielectric layer and in the memory array area and the peripheral area. The first contact is disposed in the peripheral area and electrically connected to the contact pad in the peripheral area. The isolation element is disposed in the peripheral area and between the second conductive layer and the first contact.

In some embodiments, a method for forming a semiconductor device is provided. The formation method includes providing a substrate, wherein the substrate includes a memory array area and a peripheral area adjacent to the memory array area. The formation method includes forming a contact pad on the substrate; forming a first conductive layer on the contact pad; forming a dielectric layer on the first conductive layer; forming a second conductive layer on the dielectric layer. The formation method includes forming a first opening in the peripheral area to expose a side surface of the second conductive layer. The formation method includes forming an isolation element on the side surface of the second conductive layer. The formation method includes forming a first contact in the first opening and on the isolation element, so that the first contact is electrically connected to the contact pad in the peripheral area.

### BRIEF DESCRIPTION OF THE DRAWINGS

FIGS. 1 to 8 are cross-sectional views of various stages of a method for forming a semiconductor device according to some embodiment of the present disclosure, respectively.

FIGS. 9 to 12 are cross-sectional views of various stages of a method for forming a semiconductor device according to some embodiment of the present disclosure, respectively.

### DETAILED DESCRIPTION

The following embodiments are described in detail with reference to the accompanying drawings. However, the embodiments provided herein are not intended to limit the scope of the present disclosure. For ease of understanding, the same reference numerals will be used to denote the same elements in the following description.

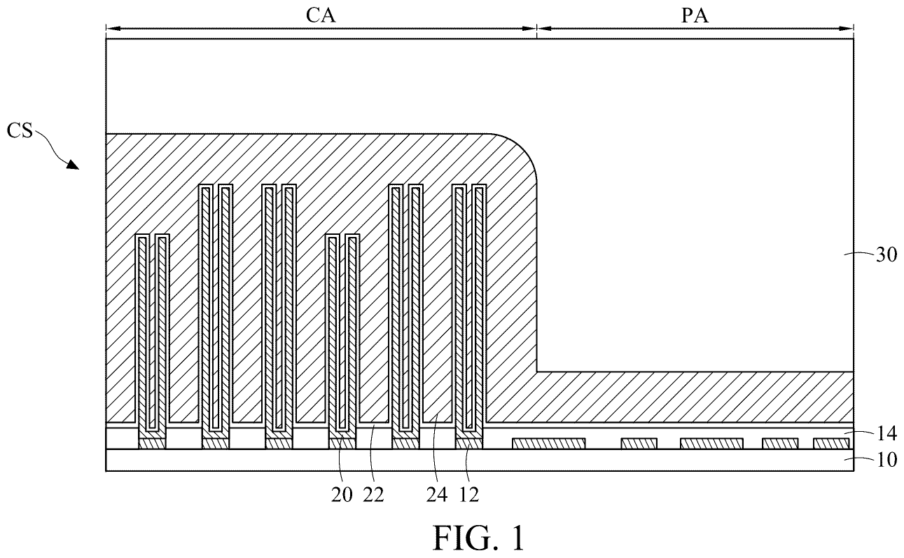

FIGS. 1 to 8 are cross-sectional views of various stages of a method for forming a semiconductor device according to some embodiment of the present disclosure, respectively. Referring to FIG. 1, a substrate 10 may be provided. The substrate 10 may include a memory array area CA and a peripheral area PA, and the peripheral area PA may be adjacent to the memory array area CA. The substrate 10 may be a wafer such as a silicon wafer, a semiconductor-on-insulator substrate, or a bulk semiconductor substrate. The substrate 10 may be a multilayer substrate or a gradient substrate. The substrate 10 may include an elemental semiconductor such as silicon and germanium; a compound semiconductor such as silicon carbide, gallium arsenide, gallium phosphide, indium phosphide, indium arsenide, and indium antimonide; an alloy semiconductor such as SiGe, GaAsP, AlInAs, AlGaAs, GaInAs, GaInP, and GaInAsP; and the like, or a combination thereof, but the present disclosure is not limited thereto. The substrate 10 may be a doped or undoped semiconductor substrate. For example, the substrate 10 may include silicon.

As shown in FIG. 1, a contact pad 12 may be provided on the substrate 10. The contact pad 12 may include a conductive material. The conductive material may include amorphous silicon; polycrystalline silicon; polycrystalline silicon germanium; a metal such as tungsten, copper, silver, gold, cobalt, and titanium; a metal nitride such as tungsten nitride and titanium nitride; a conductive metal oxide; or the like, or a combination thereof, but the present disclosure is not limited thereto. The contact pad 12 may be formed by performing a deposition process such as a chemical vapor deposition process (CVD), a physical vapor deposition process, a similar process, or a combination thereof; and performing a removal process such as an etching process, a similar process, or a combination thereof. The etching process may include dry etching and wet etching. The dry etching may include plasma etching, plasma-free gas etching, sputter etching, ion milling, reactive ion etching, a similar process, or a combination thereof, but the present disclosure is not limited thereto. The wet etching may include using an acidic solution, an alkaline solution, or a solvent to remove at least a portion of the structure to be removed. The contact pad 12 may serve as a landing pad electrically connected to a storage node contact.

As shown in FIG. 1, an insulating layer 14 may be formed on the contact pad 12. The insulating layer 14 may cover the contact pad 12 in the peripheral area PA and may expose the contact pad 12 in the memory array area CA. Therefore, the position of the electrical connection between the contact pad 12 and other components may be adjusted by controlling the pattern of the insulating layer 14. The insulating layer 14 may be a single-layer or multi-layer structure. The insulating layer 14 may include a nitride such as silicon nitride, an oxide such as silicon oxide, silicon germanium oxide, an oxynitride such as silicon oxynitride, the like, or a combination thereof, but the present disclosure is not limited thereto. For example, the insulating layer 14 may include silicon nitride. The insulating layer 14 may be formed by performing a deposition process such as a CVD process.

As shown in FIG. 1, a capacitor structure CS may be formed on the contact pad 12. In some embodiments, a conductive layer 20 may be formed on the contact pad 12 in the memory array area CA, to make the conductive layer 20 electrically connect with the contact pad 12 in the memory array area CA. The conductive layer 20 may be disposed in the memory array area CA and may not be disposed in the peripheral area PA. The material and formation method of the conductive layer 20 may be the same as or different from the material and formation method of the contact pad 12. The conductive layer 20 may include a conductive material. For example, the conductive layer 20 may include titanium nitride.

The dielectric layer 22 may be conformally formed on the conductive layer 20. The dielectric layer 22 may be disposed in the memory array area CA and the peripheral area PA. The material and formation method of the dielectric layer 22 may be the same as or different from the material and formation method of the insulating layer 14. The dielectric layer 22 may include a high dielectric constant (high-k) dielectric material. The high-k dielectric material may include a metal oxide, a metal nitride, a metal silicide, a transition metal oxide, a transition metal nitride, a transition metal silicide, a metal oxynitride, a metal aluminate, the like, or a combination thereof.

As shown in FIG. 1, a conductive layer 24 may be blanketly formed on the dielectric layer 22. The conductive layer 24 may be disposed in the memory array area CA and the peripheral area PA. The material and formation method of the conductive layer 24 may be the same as or different from the material and formation method of the conductive layer 20. The conductive layer 24 may include the conductive material. For example, the conductive layer 24 may include polycrystalline silicon germanium. The conductive layer 20 may serve as a lower electrode, the conductive layer 24 may serve as a top electrode or a cell plate, and the dielectric layer 22 may be disposed between the conductive layer 20 and the conductive layer 24. Therefore, the conductive layer 20, the dielectric layer 22, and the conductive layer 24 may together serve as a capacitor structure CS.

As shown in FIG. 1, a planarization layer 30 may be blanketly formed on the capacitor structure CS. Specifically, the planarization layer 30 may be blanketly formed on the conductive layer 24. The planarization layer 30 may be disposed in the memory array area CA and the peripheral area PA. The material and formation method of the planarization layer 30 may be the same as or different from the material and formation method of the insulating layer 14. The planarization layer 30 may have a single-layer or multi-layer structure. For example, the planarization layer 30 may include silicon oxide.

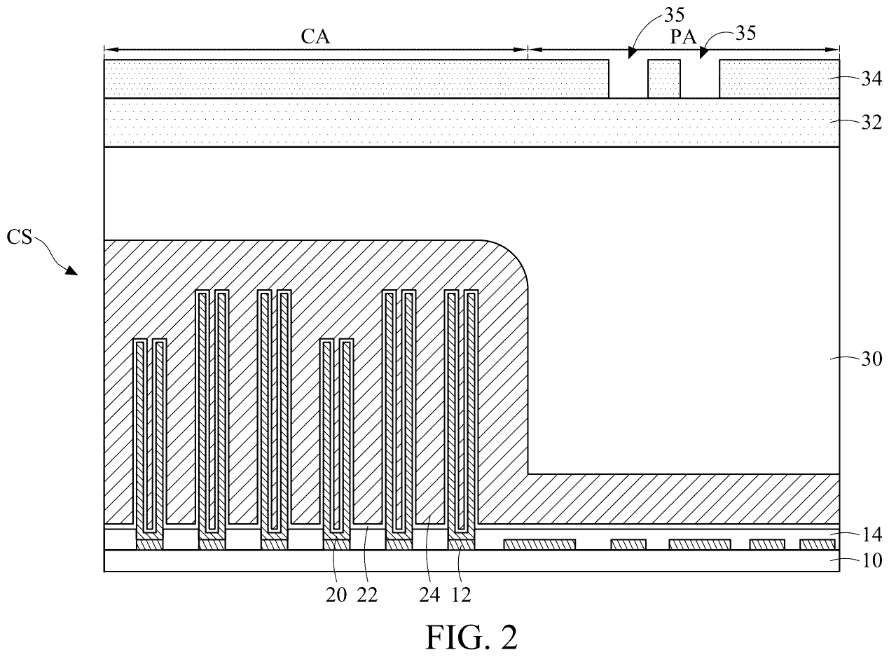

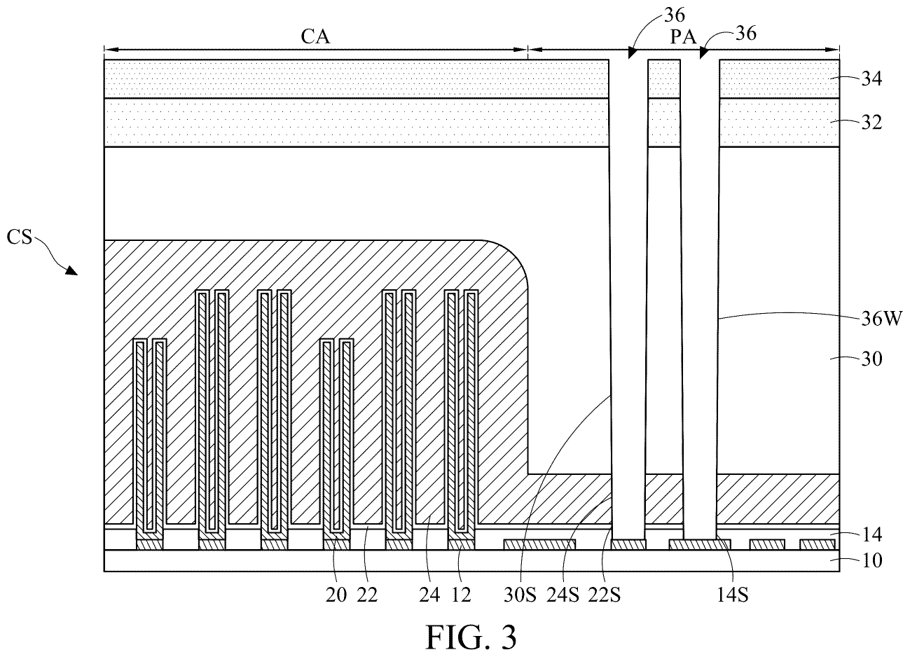

Referring to FIG. 2, a mask layer 32 may be formed on the planarization layer 30, and a photoresist layer 34 may be formed on the mask layer 32. The mask layer 32 may include a carbon-based mask. The photoresist layer 34 may include a positive-type photoresist or a negative-type photoresist. An opening 35 in the photoresist layer 34 may correspond to an opening 36 subsequently formed (as shown in FIG. 3).

Referring to FIG. 3, a first removal process may be performed to form an opening 36 in the peripheral area PA. Specifically, the opening 36 may penetrate the planarization layer 30, the conductive layer 24, the dielectric layer 22, and the insulating layer 14, and does not penetrate through the contact pad 12. The opening 36 may expose a side surface 30S of the planarization layer 30, a side surface 24S of the conductive layer 24, a side surface 22S of the dielectric layer 22, a side surface 14S of the insulating layer 14, and a top surface of the contact pad 12 in the peripheral area PA. Wherein, the first removal process may include an etching process.

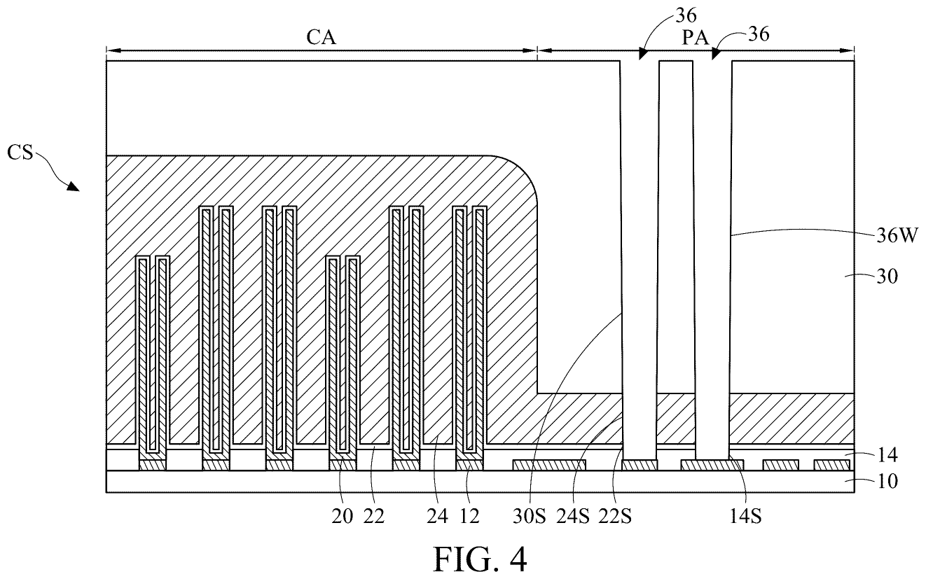

Referring to FIG. 4, the mask layer 32 and the photoresist layer 34 may be removed to expose the top surface of the planarization layer 30. The photoresist layer 34 may be removed by a removal process such as an ashing process, and the mask layer 32 may be removed by a removal process such as an etching process.

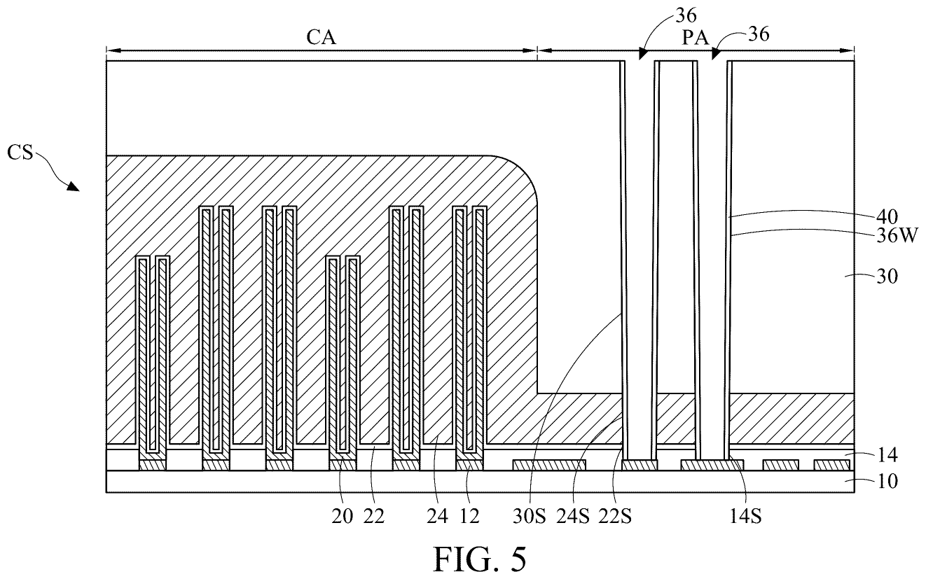

Referring to FIG. 5, an isolation element 40 may be formed in the opening 36 to cover the conductive layer 24 exposed by the opening 36. The isolation element 40 may be formed by a deposition process or an oxidation process. The isolation element 40 may include oxides such as silicon oxide, silicon germanium oxide, nitrides such as silicon nitride, oxynitrides such as silicon oxynitride, the like, or a combination thereof, but the present disclosure is not limited thereto.

In some embodiments, the material of the isolation element 40 may be conformally formed on the top surface of the planarization layer 30 and in the opening 36. For example, the material of the isolation element 40 may be formed by a deposition process such as an ALD process. Subsequently, a portion of the material of the isolation element 40 may be removed by a removal process to expose the top surface of the planarization layer 30 and the top surface of the contact pad 12. The isolation element 40 may be formed on the side surface 30S of the planarization layer 30, the side surface 24S of the conductive layer 24, the side surface 22S of the dielectric layer 22, and the side surface 14S of the insulating layer 14 exposed by the opening 36. In other words, the isolation element 40 may be formed on a sidewall 36W of the opening 36 and may substantially completely cover the sidewall 36W of the opening 36. The isolation element 40 may be in contact with the contact pad 12 in the peripheral area PA.

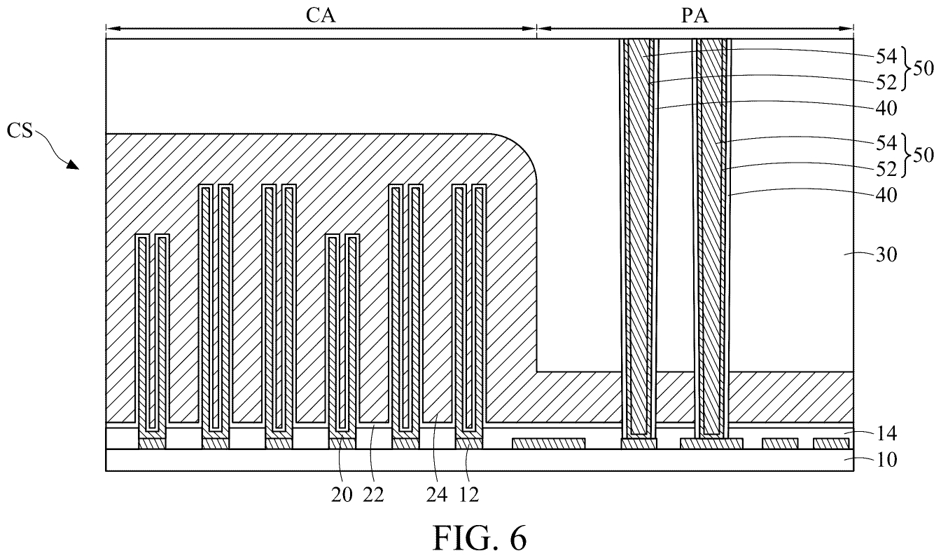

Referring to FIG. 6, a first contact 50 may be formed in the opening 36 and on the contact pad 12, to make the first contact 50 electrically connect with the contact pad 12 in the peripheral area PA. The first contact 50 may be disposed in the peripheral area PA and not in the memory array area CA. The first contact 50 may penetrate through the conductive layer 24. In some embodiments, a liner 52 may be formed in the opening 36 and on the contact pad 12, and a conductive pillar 54 may be formed on the liner 52. The materials and formation methods of the liner 52 and the conductive pillar 54 may be the same as or different from the materials and formation methods of the conductive layer 20. Next, a planarization process such as a chemical mechanical polishing (CMP) process may be performed to remove a portion of the liner 52 and a portion of the conductive pillar 54 to expose the top surface of the planarization layer 30 and form the first contact 50. The first contact 50 may include the liner 52 disposed on the contact pad 12 and the conductive pillar 54 disposed on the liner 52. For example, the liner 52 may include titanium nitride, and the conductive pillar 54 may include tungsten.

As shown in FIG. 6, the isolation element 40 may surround the first contact 50 and electrically isolates the first contact 50 from the conductive layer 24 and other components. Specifically, the isolation element 40 may be disposed at least between the conductive layer 24 and the first contact 50. The isolation element 40 may also be interposed between the conductive layer 24 and the liner 52. Thus, the isolation element 40 may prevent a short circuit between the conductive layer 24 and the first contact 50.

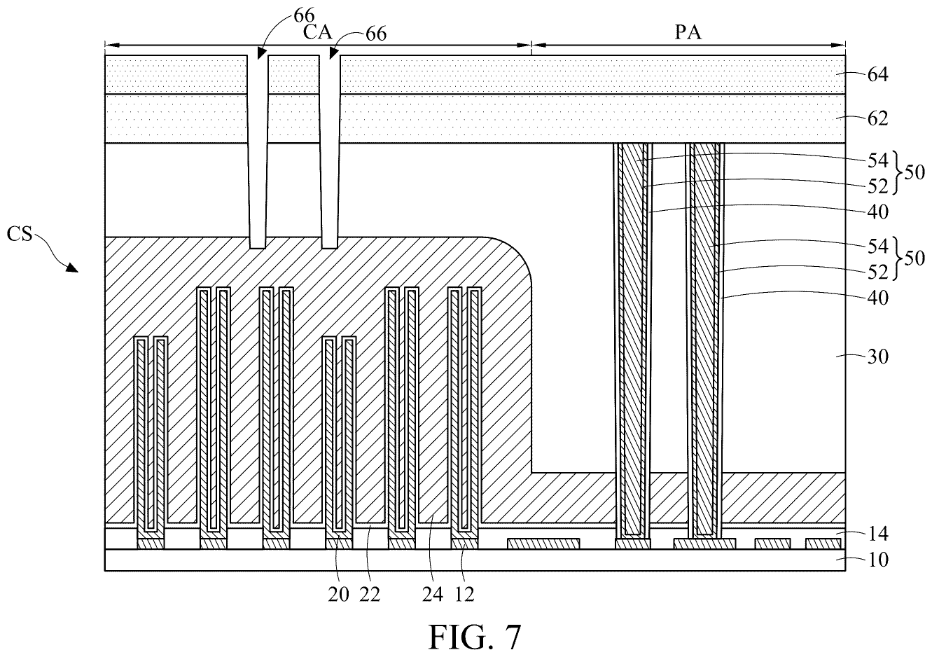

Referring to FIG. 7, a second removal process may be performed to form an opening 66 in the memory array area CA to expose the top surface of the conductive layer 24 in the memory array area CA. In some embodiments, the second removal process may be performed by forming a mask layer 62 on the planarization layer 30 and forming a photoresist layer 64 on the mask layer 62. Specifically, the opening 66 may penetrate the planarization layer 30 in the memory array area CA and may not penetrate through the conductive layer 24.

As shown in FIGS. 3 and 7, in some embodiments, the second removal process for forming the opening 66 and the first removal process for forming the opening 36 may be performed in different processes. The first removal process may be performed before the formation of the first contact 50, and the second removal process may be performed after the formation of the first contact 50. Specifically, because the first removal process causes the opening 36 to penetrate conductive layer 24 in the peripheral area PA, while the second removal process prevents the opening 66 from penetrating through the conductive layer 24 in the memory array area CA, the alignment requirement of the first removal process may be greater than the alignment requirement of the second removal process. Furthermore, because the first removal process further penetrates the conductive layer 24 and the underlying dielectric layer 22 and insulating layer 14 to expose contact pad 12, performing the first and second removal processes simultaneously may over-etch the conductive layer 24 and the underlying material in the memory array area CA. Therefore, according to the present disclosure, when the first removal process and the second removal process may be performed in different processes, it is easy to independently control the etching parameters (such as etching depth and etching time) of the first removal process and the second removal process, thereby improving the process margin of the etching process and/or avoiding damage to the capacitor structure CS in the memory array area CA.

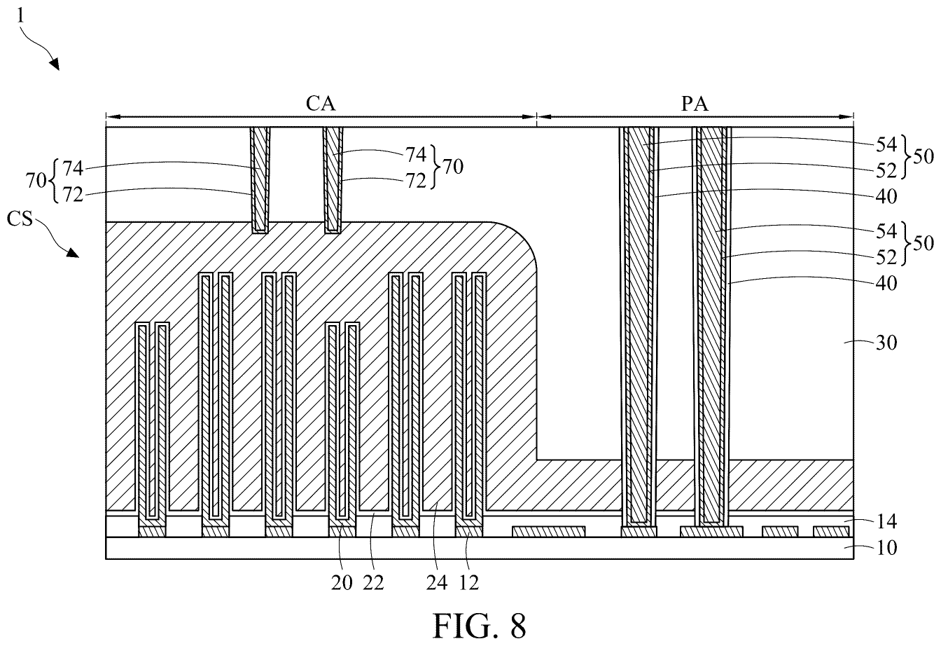

Referring to FIG. 8, a second contact 70 may be formed in the opening 66 to make the second contact 70 electrically connect with the capacitor structure CS (for example, the conductive layer 24) in the memory array area CA, thereby obtaining the semiconductor device 1. The second contact 70 may be disposed in the memory array area CA and not disposed in the peripheral area PA. The second contact 70 does not penetrate through the conductive layer 24. In some embodiments, a liner 72 may be formed in the opening 66, and a conductive pillar 74 may be formed on the liner 72. The materials and formation methods of the liner 72 and the conductive pillar 74 may be the same as or different from the materials and formation methods of the conductive layer 20. Next, a planarization process such as a CMP process may be performed to remove a portion of the liner 72 and a portion of the conductive pillar 74 to expose the top surface of the planarization layer 30 and form the second contact 70. The second contact 70 may include the liner 72 disposed on the conductive layer 24 and the conductive pillar 74 disposed on the liner 72. For example, the liner 72 may include titanium nitride, and the conductive pillar 74 may include tungsten.

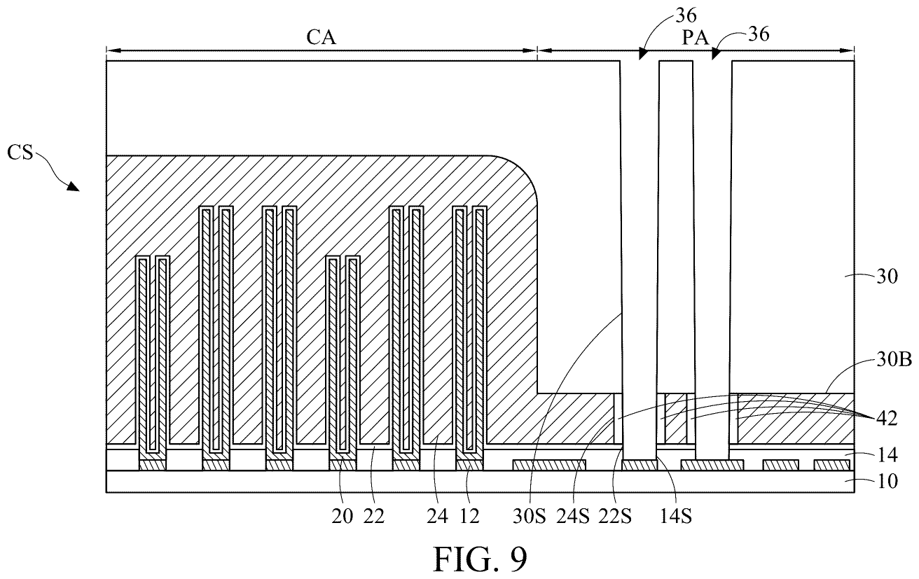

FIGS. 9 to 12 are cross-sectional views of various stages of a method for forming a semiconductor device according to some embodiment of the present disclosure, respectively. FIG. 9 may be a continuation of the process described in FIG. 4 of the previous embodiment. This embodiment may be substantially similar to the previous embodiment, with the primary difference being that the isolation element 42 of this embodiment only cover the side surface 24S of the conductive layer 24 exposed by the opening 36, the isolation element 42 does not cover the side surface 30S of the planarization layer 30, the side surface 22S of the dielectric layer 22, and the side surface 14S of the insulating layer 14.

Referring to FIG. 9, an oxidation process may be used to form the isolation element 42 in the opening 36 to cover the conductive layer 24 exposed by the opening 36. Specifically, the isolation element 42 may be formed on the side surface 24S of the conductive layer 24 exposed by the opening 36, and the isolation element 42 may not be formed on the side surface 30S of planarization layer 30, the side surface 22S of dielectric layer 22, and the side surface 14S of the insulating layer 14. As shown in FIG. 9, the oxidation process may completely oxidize the exposed conductive layer 24 in the opening 36 into the isolation element 42, thereby electrically isolating the remaining conductive layer 24 from the first contact 50 subsequently formed in the opening 36.

As shown in FIG. 9, in some embodiments, the oxidation process may include a thermal oxidation process, an in situ steam generation (ISSG) process, a similar process, or a combination thereof, but the present disclosure is not limited thereto. In embodiments which uses the oxidation process, the isolation element 42 may be an oxide formed by the oxidation process. For example, since the oxidation process may be performed on the conductive layer 24 including polycrystalline silicon germanium, the isolation element 42 may be silicon germanium oxide, but the present disclosure is not limited thereto. In some embodiments, the isolation element 42 may include an oxide of the material of the conductive layer 24. In another embodiment, the isolation element 42 may be used in combination with the isolation element 40. In this embodiment, the isolation element 42 may be used as a first sub-element and the isolation element 40 may be used as a second sub-element. The first sub-element may be disposed on the side surface 24S of the second conductive layer 24 in the peripheral area PA. The second sub-element may be disposed on the first sub-element and the side surface 22S of the dielectric layer 22 in the peripheral area PA. The second sub-element may be located between the first sub-element and the first contact 50.

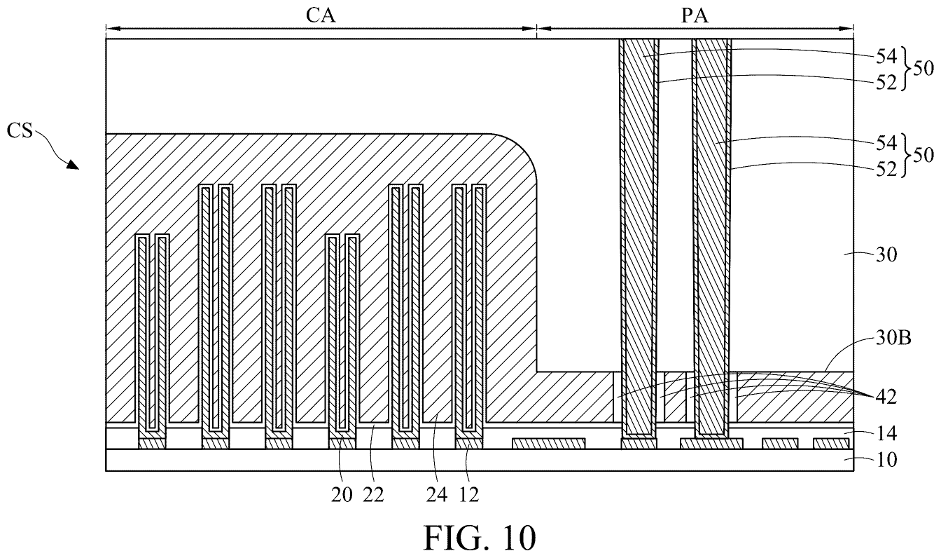

As shown in FIG. 10, similar to FIG. 6, a first contact 50 may be formed in the opening 36, and the first contact 50 may be electrically connected to the contact pad 12 in the peripheral area PA.

As shown in FIG. 10, the isolation element 42 may surround the first contact 50 and electrically isolates the first contact 50 from the conductive layer 24. Specifically, the isolation element 42 may be disposed between the conductive layer 24 and the first contact 50. The isolation element 42 may be interposed between the conductive layer 24 and the liner 52. Thus, the isolation element 42 prevents a short circuit between the conductive layer 24 and the first contact 50.

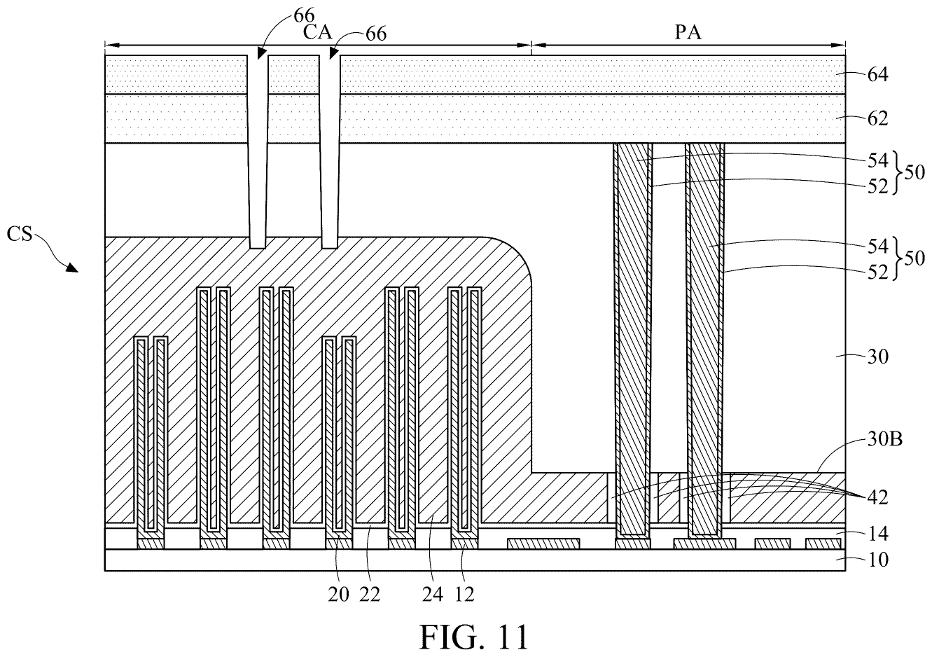

As shown in FIG. 11, similar to FIG. 7, an opening 66 may be formed in the memory array area CA to expose the top surface of the capacitor structure CS.

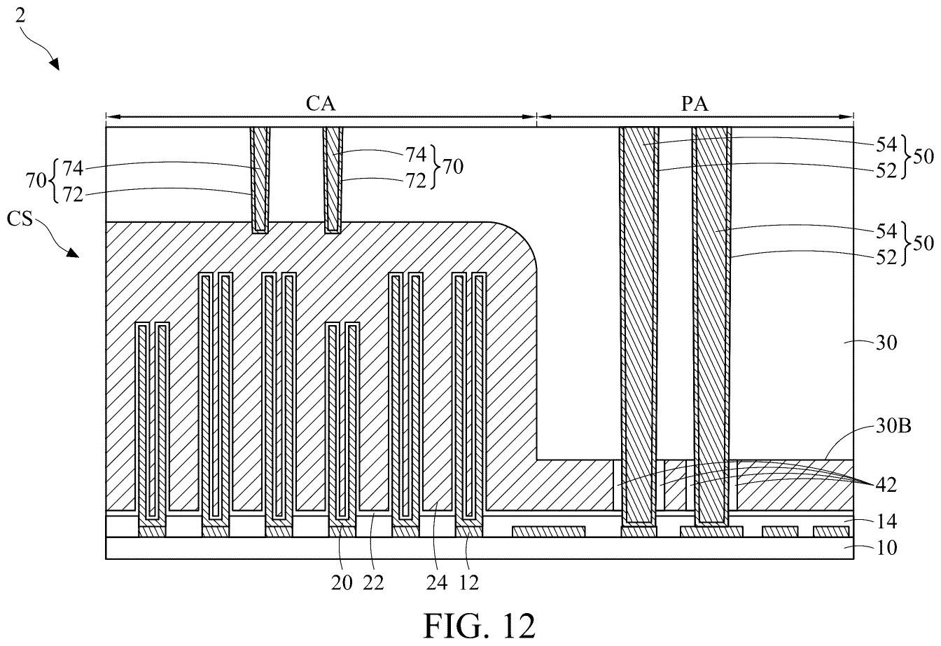

As shown in FIG. 12, similar to FIG. 8, a second contact 70 may be formed in the opening 66 to make the second contact 70 electrically connect with the capacitor structure CS in the memory array area CA, thereby obtaining the semiconductor device 2.

It should be noted that, generally, the conductive layer 24 in the peripheral area PA may be completely removed to prevent a short circuit between the conductive layer 24 and the first contact 50. However, if a removal process may be performed to completely remove the conductive layer in the peripheral area PA, under-etching may still cause a short circuit in the remaining portion of the conductive layer in the peripheral area PA, or over-etching may damage other components. In contrast, according to some embodiments of the present disclosure, after forming the conductive layer 24 and the planarization layer 30, the present disclosure directly forms the opening 36, the first contact 50, and the isolation element 40, 42 located between the conductive layer 24 and the first contact 50 in the peripheral area PA. The present disclosure does not perform an additional removal process to completely remove the conductive layer 24 in the peripheral area PA.

Therefore, by forming an isolation element between the conductive layer and the first contact in the peripheral area, the present disclosure can prevent short circuits between the first contact and the conductive layer without completely removing the conductive layer in the peripheral area. The isolation element can also ensure sufficient insulation and improve process margins (process windows). Furthermore, because the second opening and the first opening of the present disclosure are formed in separate process steps, etching parameters can be easily controlled independently, improving the process margin of the etching process and/or avoiding damage to the capacitor structure in the memory array area. Consequently, the formation method of the present disclosure can achieve the effects of preventing short circuits, providing sufficient insulation, improving electrical performance, and/or enhancing reliability.

The foregoing outlines features of several embodiments of the present disclosure, so that a person of ordinary skill in the art may better understand the aspects of the present disclosure. A person of ordinary skill in the art should realize that such equivalent processes and constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a memory array area and a peripheral area adjacent to the memory array area;
a contact pad disposed on the substrate;
a first conductive layer disposed on the contact pad and in the memory array area;
a dielectric layer disposed on the first conductive layer and in the memory array area and the peripheral area;
a second conductive layer disposed on the dielectric layer and in the memory array area and the peripheral area;
a first contact disposed in the peripheral area and electrically connected to the contact pad in the peripheral area; and
an isolation element disposed in the peripheral area and between the second conductive layer and the first contact.

2. The semiconductor device as claimed in claim 1, wherein the isolation element is disposed on a side surface of the second conductive layer in the peripheral area.

3. The semiconductor device as claimed in claim 2, wherein the isolation element is disposed on a side surface of the dielectric layer in the peripheral area.

4. The semiconductor device as claimed in claim 3, wherein the isolation element further comprising:
a first sub-element disposed on a side surface of the second conductive layer in the peripheral area; and
a second sub-element disposed on the first sub-element and a side surface of the dielectric layer in the peripheral area.

5. The semiconductor device as claimed in claim 4, wherein the second sub-element is located between the first sub-element and the first contact.

6. The semiconductor device as claimed in claim 1, wherein the isolation element surrounds the first contact.

7. The semiconductor device as claimed in claim 1, wherein the isolation element comprises an oxide of a material of the second conductive layer.

8. The semiconductor device as claimed in claim 1, wherein the isolation element is in contact with the contact pad in the peripheral area.

9. The semiconductor device as claimed in claim 1, wherein the first conductive layer is not disposed in the peripheral area.

10. The semiconductor device as claimed in claim 1, wherein the first contact penetrates through the second conductive layer.

11. The semiconductor device as claimed in claim 1, wherein the first contact further comprises:
a liner disposed on the contact pad; and
a conductive pillar disposed on the liner.

12. The semiconductor device as claimed in claim 1, further comprising:
a second contact disposed in the memory array area and electrically connected to the second conductive layer in the memory array area.

13. The semiconductor device as claimed in claim 1, wherein the second contact does not penetrate through the second conductive layer.

14. The semiconductor device as claimed in claim 12, wherein the second contact further comprises:
a liner disposed on the second conductive layer; and
a conductive pillar disposed on the liner.

15. A method for forming a semiconductor device, comprising:
providing a substrate, wherein the substrate comprises a memory array area and a peripheral area adjacent to the memory array area;
forming a contact pad on the substrate;
forming a first conductive layer on the contact pad;
forming a dielectric layer on the first conductive layer;
forming a second conductive layer on the dielectric layer;
forming a first opening in the peripheral area to expose a side surface of the second conductive layer;
forming an isolation element on the side surface of the second conductive layer; and
forming a first contact in the first opening and on the isolation element, so that the first contact is electrically connected to the contact pad in the peripheral area.

16. The formation method as claimed in claim 15, wherein the formation of the first opening in the peripheral area exposes a side surface of the dielectric layer.

17. The formation method as claimed in claim 15, wherein the formation of the isolation element on the side surface of the second conductive layer comprises:
conformally forming a material of the isolation element in the first opening; and
removing the material of the isolation element to expose the contact pad.

18. The formation method as claimed in claim 17, further comprising:
forming a planarization layer on the second conductive layer;
wherein the first opening is formed to penetrate the planarization layer and expose a side surface of the planarization layer; and
wherein the isolation element is formed on the side surface of the second conductive layer and the side surface of the planarization layer.

19. The formation method as claimed in claim 15, wherein the isolation element is formed on the side surface of the second conductive layer by performing an oxidation process on the side surface of the second conductive layer.

20. The formation method as claimed in claim 19, further comprising:
forming a planarization layer on the second conductive layer;
wherein the first opening is formed to penetrate the planarization layer and expose a side surface of the planarization layer; and
wherein the isolation element is formed and the isolation element exposes the side surface of the planarization layer.
